(19) United States
(12) Patent Application Publication
(10) Pub. No.: US 2008/0298608 A1
(43) Pub. Date: Dec. 4, 2008

(54) Sound Generating Device with Removable Memory

(76) Inventor: Clinton Wilcox, Grass Valley, CA (US)

Correspondence Address: CLINTON WILCOX, 13395 BASS TRAIL, GRASS VALLEY, CA, 95945, US

(21) Appl. No.: 11/969,884

(22) Filed: Jan. 5, 2008

Related U.S. Application Data
(60) Provisional application No. 60/941,639, filed on Jun. 1, 2007.

(51) Int. Cl. H03F 21/00; H04R 1/02; H04R 3/00

(52) U.S. Cl. 381/120; 381/386; 381/395; 381/388; 381/394

(57) ABSTRACT

A sound generating device for transforming an object into a loudspeaker is includes an exciter module adapted for receiving audio signals stored on a portable micro-memory card or the like and a mounting device connected to the exciter module for removably connecting the exciter module to an object such that the object is transformed into a loudspeaker when the exciter module is energized by the audio signals.

### CROSS REFERENCE TO RELATED APPLICATIONS

This application claims the benefit of U.S. Provisional Application No. 60/941,639 filed on Jun. 1, 2007, the disclosure of which is hereby incorporated by reference in its entirety.

This application is also related to U.S. Design Application No. 29/298,099 filed on Nov. 28, 2007, the disclosure of which is hereby incorporated by reference in its entirety and to U.S. patent Ser. No. 11/946,832 filed on Nov. 28, 2007.

### BACKGROUND OF THE INVENTION

This invention relates generally to loudspeakers, and more particularly to portable, self-contained sound generating devices that can be attached to other objects to transform such objects into loudspeakers.

Prior art loudspeakers, including cone-type speakers, headsets and in-ear speakers, have long been incorporated into or connectable to portable radios, personal media players such as MP3 players, computers, two-way communications equipment, and so on. The use of in-ear speakers is especially of concern since many users may experience some form of temporary or permanent hearing loss, especially when such devices are used over extended periods of time at loud volumes. Perhaps of even greater concern is the potential of bodily harm to the user or others while wearing in-ear speakers. The very nature of these devices dictates that they be positioned in or very close to the ear canal and, when in use, effectively drown out ambient noise. When such ambient noise includes sirens, horns and/or other warning sounds, the failure to notice such may prove fatal. In addition, such devices are typically uncomfortable to wear and difficult to use, often falling out of place during physical activity such as exercising. Also, the use of separate wires that must run from each ear to the audio source is inconvenient.

### BRIEF SUMMARY OF THE INVENTION

According to one aspect of the invention, a sound generating device for transforming an object into a loudspeaker is disclosed. The sound generating device includes a portable memory module adapted for storing audio signals, a housing having a receptacle for receiving the portable memory module, and an exciter module located within the housing and operably associated with the portable memory module for generating vibrations at audio frequencies in response to audio signals associated with the portable memory module. The exciter module is connectable to an object to vibrate the object at the audio frequencies to thereby transform the object into a loudspeaker.

According to another aspect of the invention, a loudspeaker includes the above-described sound generating device and panel attached to the exciter module. The panel may be part of a wear article such as, without limitation, a piece of clothing, helmet, cap, hat, belt, shoe or boot, and so on.

According to a further aspect of the invention, a sound generating device for transforming a panel into a loudspeaker includes a housing, a portable memory module adapted for storing audio signals, an electromechanical assembly located within the housing, and a mounting device connected to the housing for removably connecting the housing to a panel to transform the panel into a loudspeaker. The housing includes an upper housing portion connected to a lower housing portion. The lower housing portion has a movable wall section for contacting a surface of the panel. A receptacle is formed in the housing for receiving the portable memory module. The electro-mechanical assembly includes a printed circuit board mounted in the upper housing portion and a transducer that is suspended from the printed circuit board and extends into the lower housing portion. The transducer has a stationary magnet and a movable plunger with an electrical coil in electrical communication with the printed circuit board. The printed circuit board contains electrical circuitry for energizing the coil in response to a received audio signal from the portable memory module and move the plunger with respect to the stationary magnet in proportion to the received audio signal. The movable wall section is connected to a lower end of the plunger for movement therewith. When actuated, the movable wall section causes the panel to vibrate and transform the panel into a loudspeaker.

### BRIEF DESCRIPTION OF THE DRAWINGS

The foregoing summary as well as the following detailed description of the preferred embodiments of the present invention will be best understood when considered in conjunction with the accompanying drawings, wherein like designations denote like elements throughout the drawings, and wherein:

FIG. 1 is an isometric view of a sound generating device in accordance with the present invention;

FIG. 2 is a top plan view of the sound generating device;

FIG. 3 is an exploded isometric view of the sound generating device;

FIG. 4 is a sectional view of the sound generating device taken along line 4-4 of FIG. 2;

FIG. 5 is a sectional view of the sound generating device taken along line 5-5 of FIG. 2;

FIG. 5A is a sectional view similar to FIG. 5 showing a sound generating device in accordance with a further embodiment of the invention;

FIG. 6 is a bottom plan view of the sound generating device;

FIG. 7 is an isometric view of a lower housing portion of the sound generating device;

FIG. 8 is an isometric view of an upper housing portion of the sound generating device;

FIG. 9 is a bottom plan view of the upper housing portion;

FIG. 10 is a schematic diagram of electrical circuitry for operating the sound generating device in accordance with the invention;

FIG. 11 is an isometric view of a sound generating device in accordance with a further embodiment of the invention;

FIG. 12 is an isometric exploded view of the exciter module and mounting device of the sound generating device of FIG. 11;

FIG. 13 is a sectional view similar to FIG. 4 of a sound generating device in accordance with a further embodiment of the invention;

FIG. 14 is a bottom plan view of the sound generating device of FIG. 13;

FIG. 15 is a perspective view showing the sound generating device connected to the bill of a cap;

FIG. 16 is a perspective view showing the sound generating device connected to a motorcycle helmet;

FIG. 17 is a top plan view showing the sound generating device connected to a sun visor of a vehicle;

FIG. 18 is an isometric exploded view of an exciter module for insertion into a mounting device in accordance with a further embodiment of the invention;

FIG. 19 is an isometric view of a mounting device in accordance with another embodiment of the invention;

FIG. 20 is an isometric view of the sound generating device with an integrated mounting device in accordance with yet a further embodiment of the invention;

FIG. 21 is an isometric view of a sound generating device in accordance with a further embodiment of the invention showing installation of one or more portable memory modules;

FIG. 22 is an isometric view similar to FIG. 21 with the memory module installed;

FIG. 23 is a block diagram of the electronics associated with the FIGS. 21-24 embodiments;

FIG. 24 is an isometric view of a sound generating device in accordance with another embodiment of the invention showing insertion of a portable memory module; and

FIG. 25 is an enlarged side elevational view of a sound generating device with an attached mounting device in accordance with yet another embodiment of the invention.

It is noted that the drawings are intended to depict only typical embodiments of the invention and therefore should not be considered as limiting the scope thereof. It is further noted that the drawings are not necessarily to scale. The invention will now be described in greater detail with reference to the accompanying drawings.

### DETAILED DESCRIPTION OF THE INVENTION

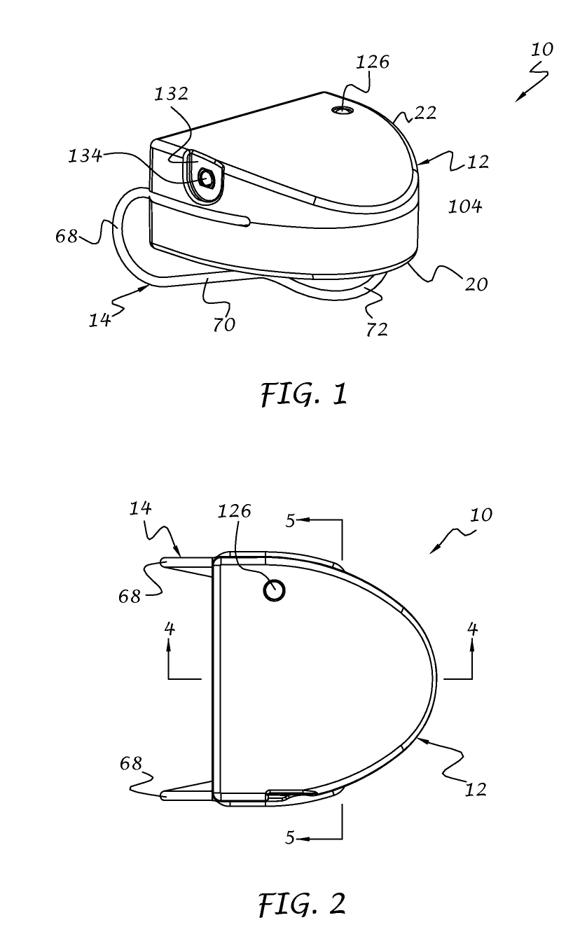

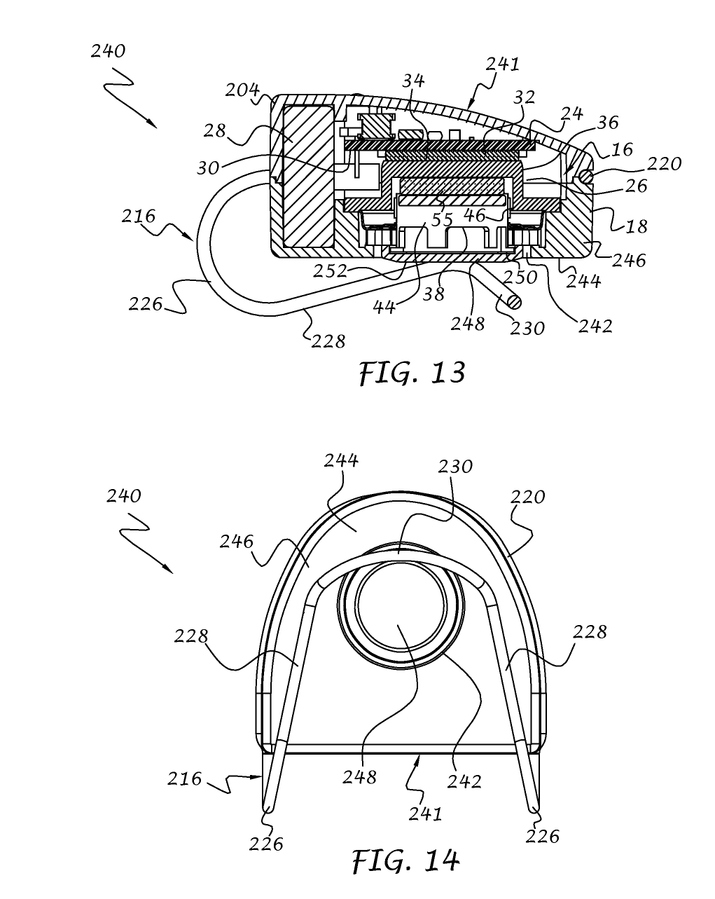

Referring now to the drawings, and to FIGS. 1, 2 and 6 in particular, a sound generating device 10 in accordance with an exemplary embodiment of the present invention preferably includes an exciter module 12 with a removable mounting device 14 for holding the exciter module against a surface such as the brim or bill of a cap or hat, a helmet or sun visor as shown for example in FIGS. 13-15 as will be described in greater detail below. Other surfaces may include, but are not limited to, binders, book covers, tickets, credit cards, pictures, walls, containers, and many other panel-like structures, whether curved and/or flat. When the exciter module 12 is in contact with the surface and driven by a suitable driving signal from an audio source, including but not limited to media players such as MP3 players, radios, microphones, phones or other signal generating devices, the surface is transformed into a loudspeaker.

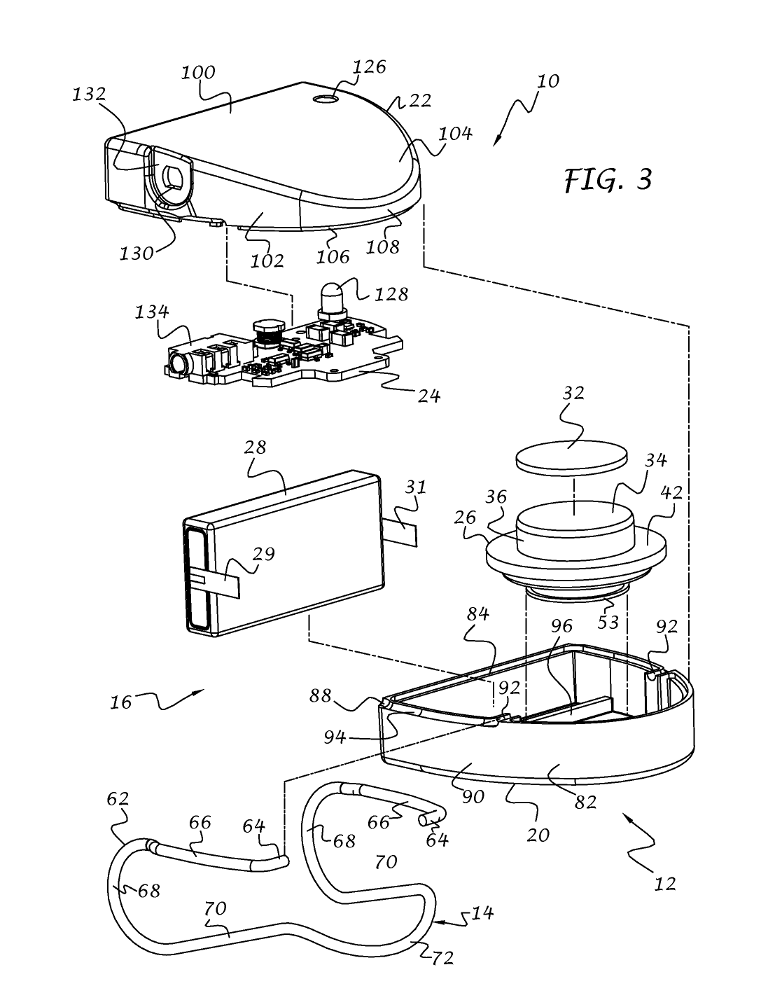

With additional reference to FIGS. 3-5, the exciter module 12 preferably includes an electro-mechanical assembly 16 located within a housing 18 comprising a lower housing portion 20 and an upper housing portion 22 that are connected together through well-known connection means, such as adhesive bonding, mechanical fastening, locking tabs, ultrasonic welding, and so on.

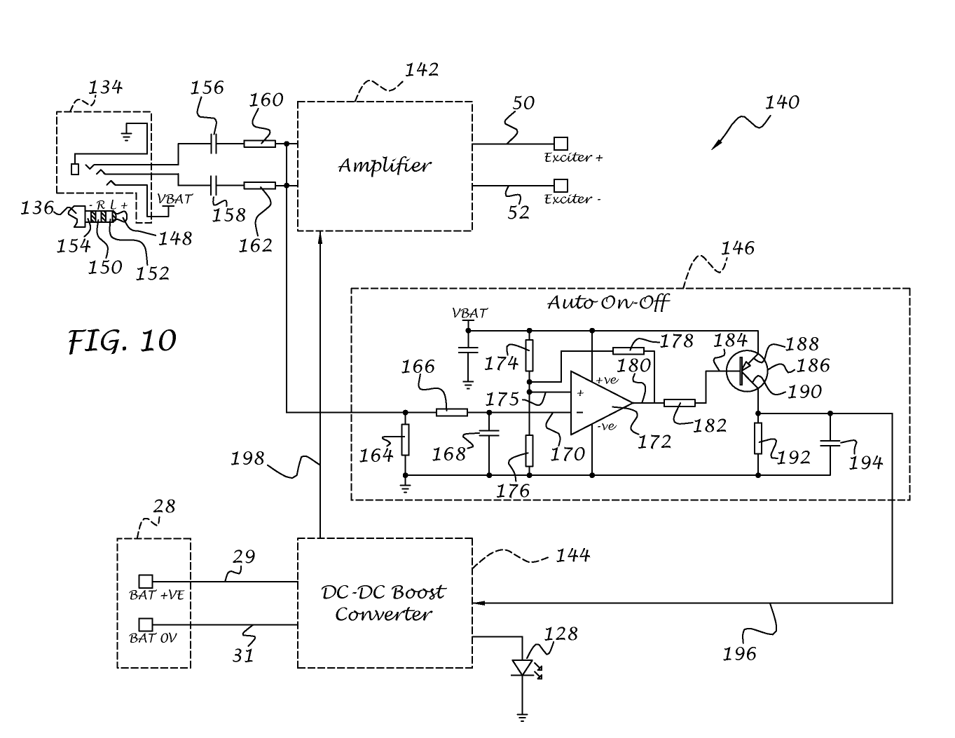

The electro-mechanical assembly 16 preferably includes a printed circuit board 24 with accompanying electronic circuitry 140 (FIG. 10) located in the upper housing portion 22, a transducer 26 extending from the upper housing portion to the lower housing portion 20, and a power supply 28, preferably in the form of a DC rechargeable battery, positioned within both housing portions. The battery 28 preferably includes a positive terminal or tab 29 and a negative or ground terminal or tab 31 that are preferably directly soldered to the circuit board 24. However, it will be understood that the battery 28 can be electrically connected in any well-known manner to the electronic circuitry. It will be further understood that the battery may be replaceable rather than rechargeable and/or an external power supply (not shown) may be used for directly or indirectly powering the exciter module 12.

A foam pad 32 is preferably adhesively connected to a lower surface 30 of the circuit board 24 and an upper wall 34 of the transducer 26 so that the transducer is suspended from the circuit board. The foam pad 32 can be constructed of an elastomeric material and serves as a shock absorber for the transducer 26 and circuit board 24 in the event that the sound generating device 10 is dropped or otherwise subjected to impact forces.

The transducer 26 preferably includes a cap-shaped stationary permanent magnet 36 with an upper surface 34 attached to the foam pad 32 and a movable coil assembly 38 connected to the permanent magnet 36 via a corrugated membrane 40 that extends between a lower flange 42 of the magnet 36 and a plunger 44 of the coil assembly 38. The membrane 40 ensures axial movement of the plunger 44 with respect to the magnet 36. Preferably, the plunger is of generally hollow tubular configuration. An electrical coil 46 is wrapped around an upper end of the plunger 44 and fixed thereto by epoxy resin or the like. The coil 46 has a pair of electrical leads 50, 52 (FIG. 10) that connect to the circuit board 24 for receiving audio signals. The audio signals in turn energize the coil assembly, causing the plunger 44 to vibrate in an axial direction having an amplitude and frequency proportional to the audio signals. A plurality of feet 48 are preferably located at a lower end of the plunger 44 and are adapted to contact a lower movable wall section 54 of the lower housing portion 20 so that the wall section 54 vibrates at the same amplitude and frequency as the plunger 44. Preferably, an adhesive ring 53 (FIG. 3) connects the movable wall section 54 to the plunger 44. However, it will be understood that the plunger may be connected to the wall section 54 through any well known connection means. A second foam pad 55, which can also be constructed of elastomeric material, is preferably positioned between the plunger 44 and the magnet 36 to prevent damage to the plunger during axial movement.

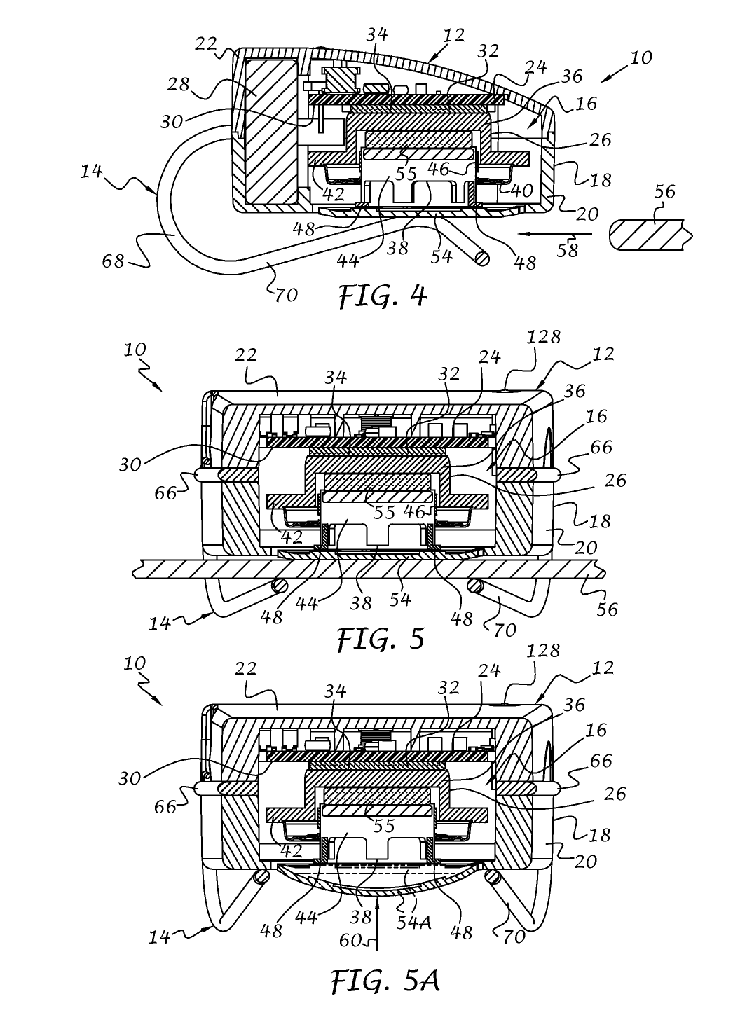

When a panel 56 is inserted between the mounting device 14 and the exciter module 12, as shown by arrow 58 in FIG. 4, the panel will come in contact with the movable wall section 54, as shown in FIG. 5. When the plunger 44 vibrates in response to audio signals, the panel will also vibrate and thus be transformed into a loudspeaker. Sound generated through the panel by the exciter module 12 is preferably much greater in volume than sound that may be generated by the exciter module alone. In accordance with one embodiment of the present invention, the feet 48 are adhesively bonded or otherwise secured to the lower movable wall section 54 so that low volume sound may be generated by the wall section 54 without connection to a panel. In this manner, a user may readily discern when the unit is operating.

In accordance with a further embodiment of the invention, and with reference to FIG. 5A, the lower movable wall section 54A is preferably semi-circular in cross section so that the feet 48 are spaced away from the wall section when no panel is present. In this condition, little or no sound is generated by the exciter module 12 during operation since the plunger 44 is moving in air. When a panel is inserted between the mounting device 14 and exciter module 12 as previously described, the lower movable wall section 54A will be forced into direct contact with the feet 48, as represented by arrow 60 and as shown by phantom line. In this condition, the panel is transformed into a loudspeaker with a surprising amount of volume and clarity with little or no perceivable distortion.

Although the transducer has been shown and described with a stationary magnet and movable coil, it will be understood that the magnet may be movable and the coil may be stationary. It will be further understood that the present invention is not limited to transducers with magnet and coil arrangements but may alternatively or additionally include piezoelectric transducers or any other arrangement that causes vibration in a panel in response to audio signals. Suitable transducers are disclosed in U.S. Pat. Nos. 7,151,837, 6,332,029 and 6,192,136, the disclosures of which are hereby incorporated by reference.

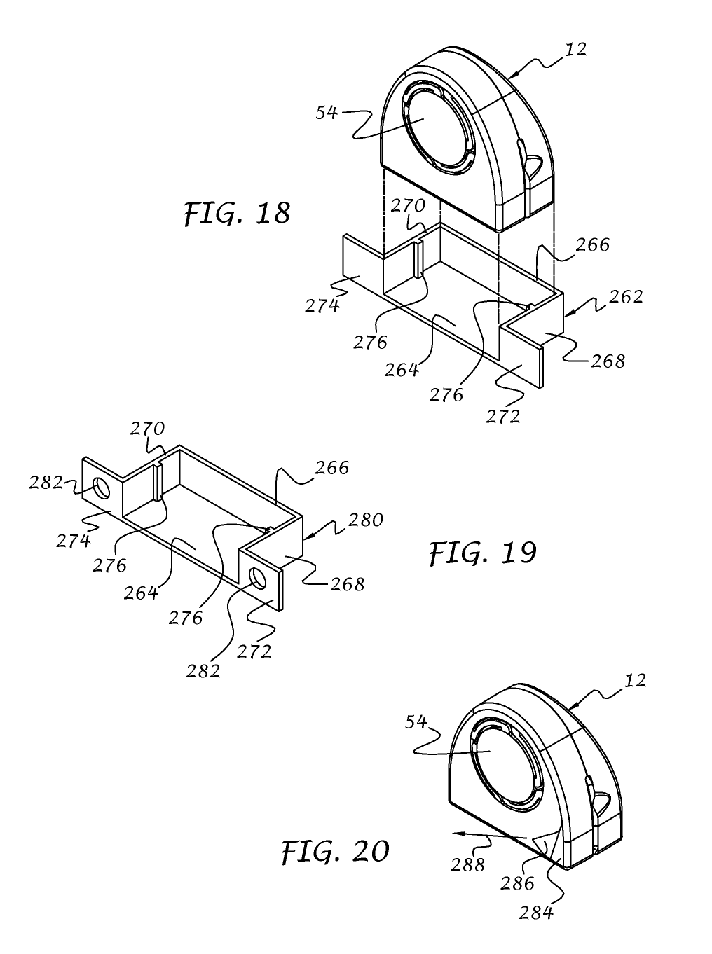

As best shown in FIGS. 1, 3 and 6, the mounting device 14 is preferably in the form of a removable spring clip 62 with opposing end segments 64, first curved segments 66 extending rearwardly from the end segments 64, second curved segments 68 extending downwardly from the first curved segments 66, slanted segments 70 extending forwardly and upwardly from the second curved segments 68, and a third curved segment 72 extending between the slanted segments 70. Preferably, the segments 64-72 are constructed of a single rod or wire that has been bent or otherwise formed into the illustrated shape. The rod is constructed of a resilient material, such as stainless steel or other metals, plastic, and so on, so that the end segments 64 can be inserted into and removed from the housing portions 20, 22. In addition, the segments 66-70 function to frictionally hold a panel 56 between the spring clip 62 and the exciter module 12. The removable nature of the spring clip 62 allows the exciter module to be used with other mounting arrangements, such as a holster 262 shown in FIG. 18 or an adhesive layer 284 shown in FIG. 20 for directly connecting the exciter module 12 to a surface.

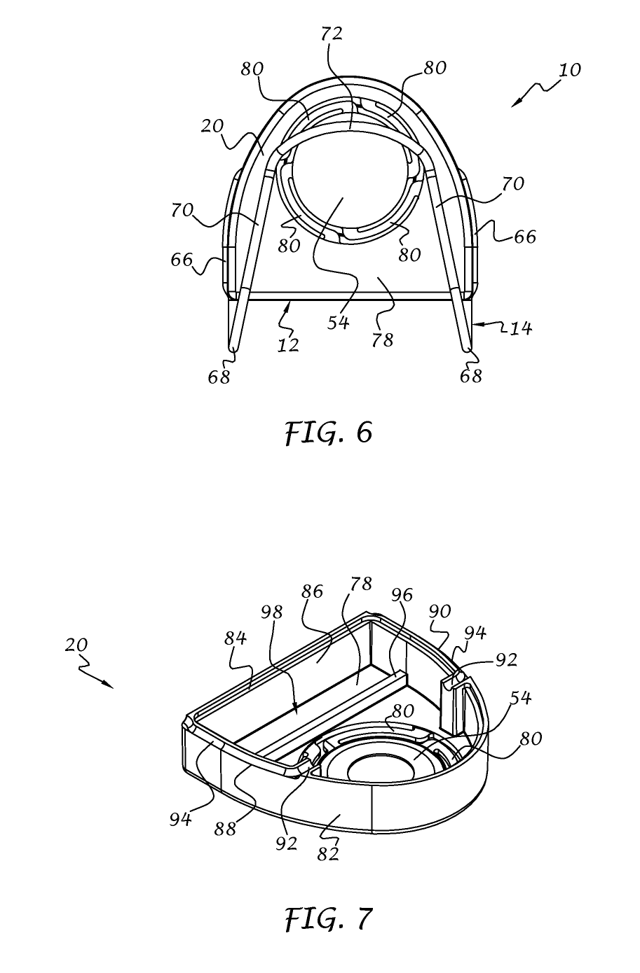

Referring now to FIGS. 6-7, the lower housing portion 20 preferably includes the lower movable wall section 54 connected to a lower wall 78 by a plurality of S-shaped flexible webs 80. A continuous side wall 82 extends around the periphery of the lower wall 78 and upwardly therefrom. A step 84 is formed on an inner surface 86 of the side wall 82 for mating with the upper housing portion 22. Grooves 88 and 90 are formed on opposite sides of the wall 82. Each groove includes a transverse segment 92 that extends through a thickness of the side wall 82 and a curved segment 94 that extends along the side wall. The transverse segments 92 and curved segments 94 are shaped to receive the opposing end segments 64 and the first curved segments 66, respectively, of the spring clip 62. A rib 96 extends laterally across the lower wall 78 to create a compartment 98 for receiving a lower end of the battery 28.

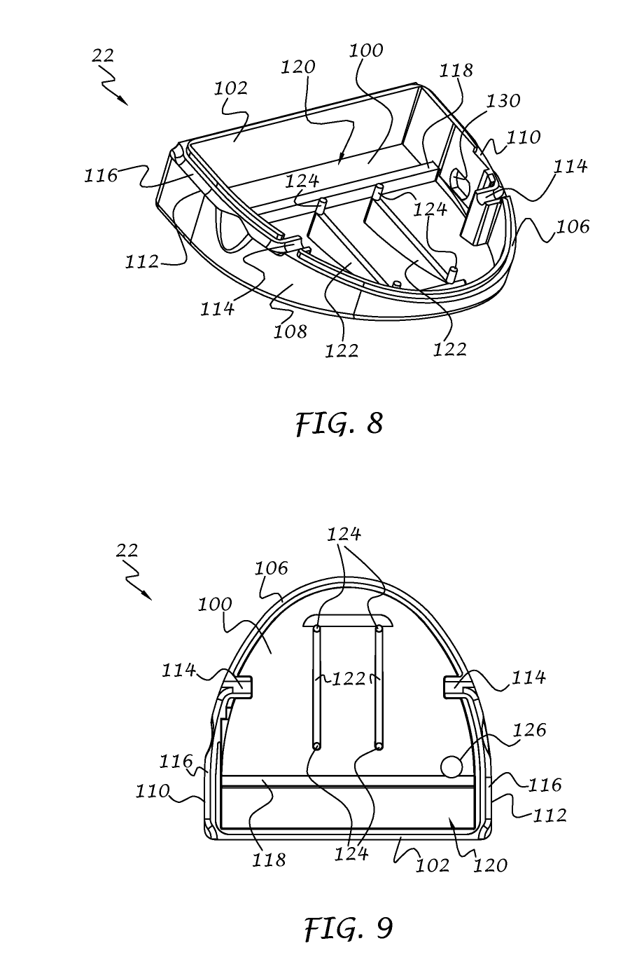

Referring now to FIGS. 3, 8 and 9, the upper housing portion 22 preferably includes an upper wall 100 and a continuous side wall 102 extending around the periphery of the upper wall 100 and downwardly therefrom. The upper wall preferably includes a curved portion 104 that extends generally downwardly and forwardly to give a low profile appearance when the housing portions 20, 22 are assembled together. A step 106 is formed on an outer surface 108 of the side wall 102 for mating with the step 84 of the lower housing portion 20. Grooves 110 and 112 are formed on opposite sides of the side wall 102. Each groove includes a transverse segment 114 that extends through a thickness of the side wall 102 and a curved segment 116 that extends along the side wall 102. As with the lower housing portion 20, the transverse segments 114 and curved segments 116 of the upper housing portion 22 are shaped to receive the opposing end segments 64 and the first curved segments 66, respectively, of the spring clip 62. A rib 118 extends laterally across the upper wall 100 to create a compartment 120 for receiving an upper end of the battery 28. A pair of extensions 122 extend longitudinally along the upper wall 100 and downwardly therefrom for receiving the circuit board 24. A boss 124 is located at each end of the extensions 122 and extend downwardly therefrom for ensuring proper alignment of the circuit board 24 with the upper housing portion 22. An opening 126 is preferably formed in the upper wall 100 and is sized to receive an indicator light, such as LED 128, which is in turn connected to the circuit board 24. An opening 130 is also preferably formed in a depression 132 of the side wall 102 for receiving a jack socket 134, which is in turn connected to the circuit board 24. The jack socket 134 is adapted to receive a jack plug 136 (FIG. 10) for delivering audio signals from media players such as MP3 players, radios, microphones, phones or other signal generating devices to the electrical circuitry 140 (FIG. 10).

Referring now to FIG. 10, the circuit board 24 contains electrical circuitry 140 for driving the transducer 36 and preferably includes an audio amplifier section 142, a DC-DC boost converter section 144, and an auto on-off section 146 that supplies power to the amplifier section 142 and converter section 144 when an audio signal is detected and cuts power from the sections 142, 144 in the absence of an audio signal. The audio amplifier section 142 serves to amplify the audio signal received via the jack plug 136 while the converter section 144 boosts the voltage output of the battery to meet the requirements of the electrical circuitry components. The sections 142 and 144 are preferably of well-known conventional construction and therefore will not be further described. It will be understood that one or both sections 142, 144 may be eliminated depending on the capability of the battery as well as the strength of the audio signal and the desired audio output.

The jack plug 136 and corresponding jack socket 134 preferably include a positive terminal 148, a right channel audio input 150 a left channel audio input 152, and a ground terminal 154.

The positive terminal 29 of the rechargeable battery 28 is electrically connectable to the positive terminal 148 to allow both fast charging and trickle charging by an external power supply. With trickle charging for example, a resistor (not shown) can be connected in series with a +5V power supply from a wall transformer, vehicle power socket, USB connector, and so on. For a 1.2V 750 mAHr NiMH rechargeable battery, the external power supply preferably supplies electrical current to the battery in the range of about 60-75 mA, allowing it to be fully charged in about 10 to 15 hours. With trickle charging, the power may be left on indefinitely without the risk of overcharging causing hazard. It will be understood that the above values are given by way of example only and are not intended to limit the scope of the invention.

A fast charger circuit (not shown) may also be electrically connected to the positive terminal 29 of the battery 28 via the positive terminal 148. Fast charging will be typically 30 minutes to 2 hours depending on the amount of available current. The external fast charger circuit will monitor the charging voltage slope with time. As the battery charges up, the charge voltage slope reduces continually and the external charger will monitor this slope and terminate the charging process when this slope reaches a predetermined value as recommended by the battery manufacturer. If the slope does not reach this level then charging is terminated after a predetermined time period. Direct access to the battery terminal is preferably for the fast charging process and for this reason the positive battery terminal 29 is directly connected to the positive terminal 148 of the jack socket 134. Construction and operation of the fast charger circuit is well known and therefore will not be further described.

The right channel audio input 150 and left channel audio input 152 are preferably electrically connectable to audio signals generated by audio sources including but not limited to media players such as MP3 players, radios, microphones, phones or other signal generating devices. By way of example, each channel may have a nominal input level of 500 mV RMS, although it will be understood that the present invention may be constructed to have higher or lower nominal input levels. The ground returns for the audio input and battery 28 are connected to the ground terminal 154.

The left and right audio inputs are preferably AC coupled by capacitors 156 and 158 and summed by resistors 160 and 162, respectively, to provide a mixed mono input to both the auto on-off section 146 and the audio amplifier section 142. The mixed mono input is pulled down by resistor 164 and fed via a low pass RC filter comprising resistor 166 and capacitor 168. Values of the resistors and capacitors are preferably chosen so that a cut off frequency of about 48 KHz results. This allows audio signals through and minimizes pick up from spurious RF signals which might otherwise wake up the exciter module. However, it will be understood that the cut off frequency can be higher or lower. The low pass filtered signal is fed to the inverting input 170 of a micro power comparator 172 which is preferably powered directly from the battery and stays active all the time. The non-inverting input 175 is preferably held at about +17 mV to +3.6 mV by the potential divider comprising resistors 174 and 176 which are connected between the battery and ground. It will be understood that the inverting input may be held at different voltages. The non-inverting input 175 of the comparator 172 is connected between the resistors 174, 176. A Schmitt trigger positive feed back includes a resistor 178 connected between the output 180 and the non-inverting input 175 of the comparator 172 in order to reject RF spurious device switching. A small capacitor (not shown) in parallel with or in place of the resistor 178 could be used to reject RF spurious device switching even further.

The output from the comparator 172 is fed through a limiting resistor 182 to the base 184 of a small signal PNP transistor 186. The emitter 188 of the transistor 186 is connected to the battery voltage and the collector 190 is connected to ground via resistor 192 and capacitor 194 and to the input of the converter section 144 via line 196.

In operation, when there is no audio signal, the non-inverting input 175 of the comparator 172, which is at +17 mV or +3.6 mV in this example, exceeds the inverting input 170 which is at ground (0V). The output of the comparator is thus at battery voltage (+1.2V in this example) and so is the base 184 of the transistor 186 which is therefore turned off with no current flowing. The collector 188 is therefore pulled to 0V which is output on line 196 to keep the boost converter section 144 in a sleep mode, consuming only a few micro-amps. When the boost converter section 144 is in the sleep mode, the amplifier section 142 will also be in the sleep mode via 0V on line 198 which electrically connects the sections 142 and 144, again only consuming a few micro-amps. The LED 128 will also be off, visually indicating that no audio signal is present and/or that the battery has an insufficient charge. Although the micro-power comparator 172 is on throughout the sleep mode it is not driving the transistor 188 so its current consumption is also minimal at a few micro-amps. Accordingly, for the given example, the battery current consumption is less than about 50 micro amps when the sections 142, 144 are in sleep mode, ensuring a very long battery life.

When an audio signal appears at the input jack a mixed mono signal of more than 17 mV (or 3.6 mV) for the given example, will appear at the inverting input 170 of the comparator 172. This will cause the comparator output 180 to go low (0V) switching on the transistor 186 and immediately charging the capacitor 194 causing line 196 to go to battery voltage (1.2V in the example) within a few microseconds. This switches on the converter section 144 preferably have a soft start and generate 5V within about 500 us, with the given example. This in turn actuates the LED 128 and turns on the amplifier section 142 for amplifying the audio signals to the coil 46 of the transducer 26 (FIGS. 4, 5 & 5A) via the electrical leads 50, 52.

The values of the resistor 192 and capacitor 194 are preferably selected to give a time constant of about five seconds. Accordingly, if no audio signal is present for more than about 5 seconds, the comparator 172 switches off the transistor 186. However, the line 196 continues to remain higher than the switching threshold voltage of the converter section 144 for about 10 seconds as capacitor 194 discharges through resistor 192. Once discharged, the voltage on line 196 is lower than the threshold voltage of the converter section 144 to thereby put the converter section into sleep mode and turn of the LED and amplifier section 142. If however the loss of audio signal is less than 5 to 10 seconds, which shorter times might be typical gaps in music play or very quiet periods in some music, then line 196 remains effectively on even with short intentional gaps in the audio signal. Accordingly, the auto on-off circuit section 146 serves to preserve battery life when no audio signal is present, automatically turn on the unit when audio signals are present, and keep the unit on during gaps or quiet periods in the music. It will be understood that the invention is not limited to the exemplary times and values given above as these times and values may greatly vary.

It will be understood that the auto on-off section 146 may be supplemented by or replaced with a manually actuated switch or the like. It will be further understood that the audio signals may additionally or alternatively be received via a wireless transmitter/receiver system such as Bluetooth™ or the like.

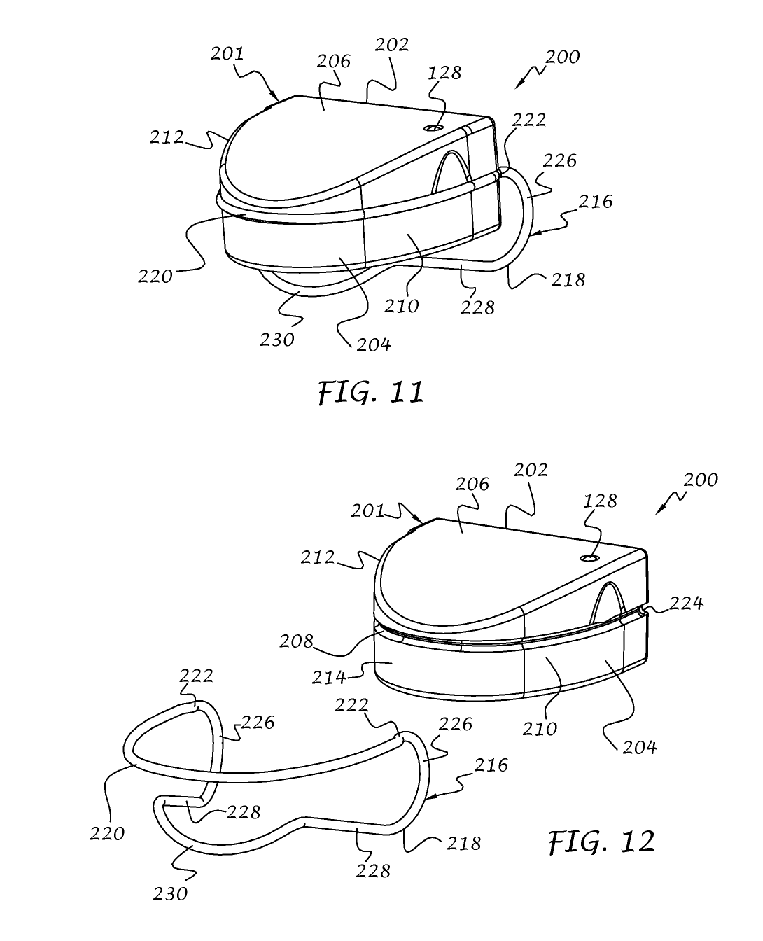

Referring now to FIGS. 11 and 12, a sound generating device 200 in accordance with a further embodiment of the invention is illustrated. The sound generating device 200 is similar in construction to the sound generating device 10 previously described, with the exception that the exciter module 201 includes a housing 202 with a lower housing portion 204 and upper housing portion 206 that are shaped to form a groove 208. Preferably, the groove 208 extends around the sides 210, 212 and front 214 of the housing 202 for receiving a removable mounting device 216 in the form of a spring clip 218.

The spring clip 218 preferably includes a first curved segment 220 that is shaped to hug the groove 208 extending along the front and sides of the housing 202, second curved segments 222 extending rearwardly and inwardly from opposite sides of the first curved segment to engage rear segments 224 (only one shown in FIG. 12) of the groove 208, third curved segments 226 extending downwardly from the second curved segments 222, slanted segments 228 extending forwardly and upwardly from the third curved segments 226, and a fourth curved segment 230 extending between the slanted segments 228 to form a continuous loop. Preferably, the segments are constructed of a single rod or wire that has been bent or otherwise formed into the illustrated shape. The rod is constructed of a resilient material, such as stainless steel or other metals, plastic, and so on, to frictionally hold a panel between the spring clip 218 and the exciter module 201 as previously described.

To install the spring clip 218 on the exciter module 201, the curved sections 220, 222 are aligned with the groove 208 and the spring clip 218 is moved rearwardly with respect to the exciter module until the curved sections 222 engage the groove 208. The rearwardly diverging shape of the housing 202 facilitates separation the curved sections 222 as the spring clip 218 is moved rearwardly with respect to the exciter module 201. Once installed, the curved sections 222 will move toward each other in a snapping action while the curved section 220 is drawn into the groove 208. Removal of the spring clip 218 is accomplished by spreading the curved sections 222 apart and moving the spring clip forward with respect to the exciter module 201.

Referring now to FIGS. 13-14, a sound generating device 240 in accordance with a further embodiment of the invention is illustrated. The sound generating device 240 is similar in construction to the sound generating device 200 previously described, with the exception that the exciter module 241 includes a circular opening 242 formed in the lower wall 244 of the lower housing portion 246 and a lower movable wall section 248, preferably in the form of a disk, inserted in the opening 242. The movable wall section 248 is connected to the plunger 44, preferably through an adhesive ring 250 located between the wall section and plunger, so that movement of the plunger causes corresponding movement of the wall section 248. It will be understood that the wall section 248 can be connected to the plunger through any well known connection means such as adhesive bonding, friction fitting, welding, integral molding, interlocking tabs, mechanical fastening, and so on. The wall section 248 preferably has a lower surface 252 that projects below the bottom wall 244 of the lower housing portion 246 so that the wall section 248 is in solid contact with a surface when sandwiched between the spring clip 218 and the lower wall 244 to ensure good vibrational coupling between the wall section 248 and panel. With this arrangement, little or no sound is generated by the exciter module 12 during operation until a panel is inserted between the spring clip 218 and wall section 248 whereupon the wall section is forced into direct contact with the panel to thereby transform the panel into a loudspeaker.

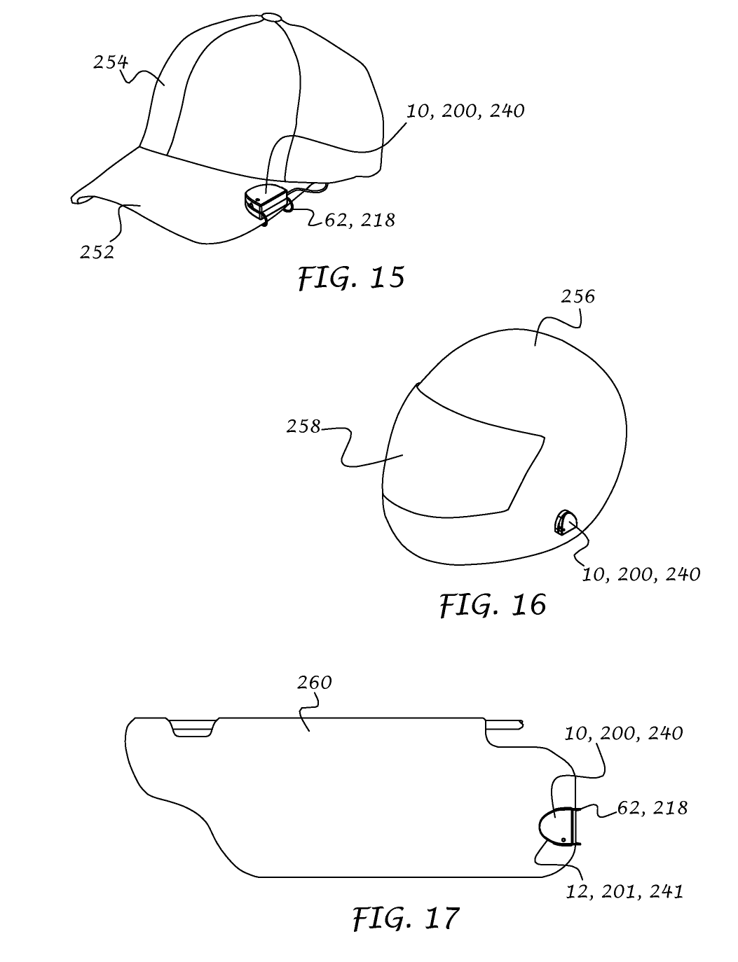

Referring now to FIG. 15, a sound generating device 10, 200 or 240 is shown mounted on the bill or brim 252 of a cap 254 such that the brim is sandwiched between the spring clip 62 or 218 located on one side of the brim 252 and the exciter module 12, 201 or 241 located on the opposite side of the brim to thereby transform the entire brim into a loudspeaker during operation. Although the sound generating device is shown in an upright position and at a particular location on the brim 252, it will be understood that the device may be positioned upside-down and/or at any location on the brim. When the material of the cap 254 or portions thereof are constructed of sufficiently stiff material, the sound generating device may alternatively placed at any location on the cap or brim.

Referring now to FIG. 16, a sound generating device 10, 200 or 240 is shown mounted directly on a helmet 256 without the spring clip 62 or 218 to transform the helmet 256 into a loudspeaker that can best be heard when the helmet is worn by a user. With the sound generating device mounted on the left side of the helmet as shown, most of the sound will be heard by the left ear. Likewise, when the sound generating device is mounted on the right side of the helmet, most of the sound will be heard by the right ear. This is particularly advantageous in some jurisdictions where sound may be permitted only in one ear when operating a motor vehicle, such as a motorcycle. Likewise, it has been found that a high center position gives approximately equal volume to each ear so that a surround sound effect occurs. It will be understood that the sound generating device 10, 200 and 240 may be mounted to the facemask 258 as well as other types of protective gear such as hardhats, bicycle safety helmets, sports helmets, and so on.

Referring now to FIG. 17, a sound generating device 10, 200 or 240 is shown mounted on a vehicle's sun visor 260 such that the sun visor is sandwiched between the spring clip 62 or 218 located on one side of the visor 260 and the exciter module 12, 201 or 241 located on the opposite side of the visor to thereby transform the entire visor into a loudspeaker during operation. Although the sound generating device is shown at a particular location and orientation on the visor 260, it will be understood that the unit may be positioned at any location and/or in any orientation on the visor.

Turning now to FIG. 18, a mounting device 262 for use with one of the exciter modules in accordance with a further embodiment of the invention is illustrated. Although the exciter module 12 is shown, it will be understood that other exciter module modules such as 201 and 241 can be used with the mounting device 262. The mounting device 262 is preferably in the form of a holster and includes a rear wall 265, a top wall 266 extending forwardly from the rear wall, side walls 268, 270 extending downwardly from the top wall 266 and forwardly from the rear wall 264, and mounting tabs 272 and 274 extending outwardly from the side walls 268 and 270, respectively. Each side wall 268, 270 has an inwardly projecting rib 276 that engages the opposing grooves of the exciter unit 12 to thereby align the exciter unit with the holster. The exciter unit can be retained on the mounting device 262 and the mounting tabs 274 can be connected to a surface or panel through any well known connecting means such as straps, magnetic attraction, hook and loop fasteners, and so on.

Referring now to FIG. 19, a mounting device 280 in accordance with a further embodiment of the invention is illustrated. The mounting device 280 is similar in construction to the mounting device 262 previously described with the exception that holes 282 are formed in the tabs 272, 274 for receiving fasteners (not shown) or the like to secure the mounting device to a the surface of an object.

Referring now to FIG. 20, a mounting device in accordance with a further embodiment of the invention includes a first layer 284 fixedly attached to the exciter module 12 and a second layer 286 adhered to the first layer 284. The first layer 284 can include an adhesive layer and the second layer 286 can include a backing sheet for protecting the adhesive layer. The backing sheet can be removed in a direction as illustrated by arrow 288 prior to use.

In accordance with a further embodiment of the invention, the first layer 284 can include one of a hook and loop material and the second layer 286 can include the other of the hook and loop material for removably connecting one of the exciter modules 12, 201, 241 to a surface. It will be understood that the exciter module can be connected to the surface of a panel or object through other well known connection means.

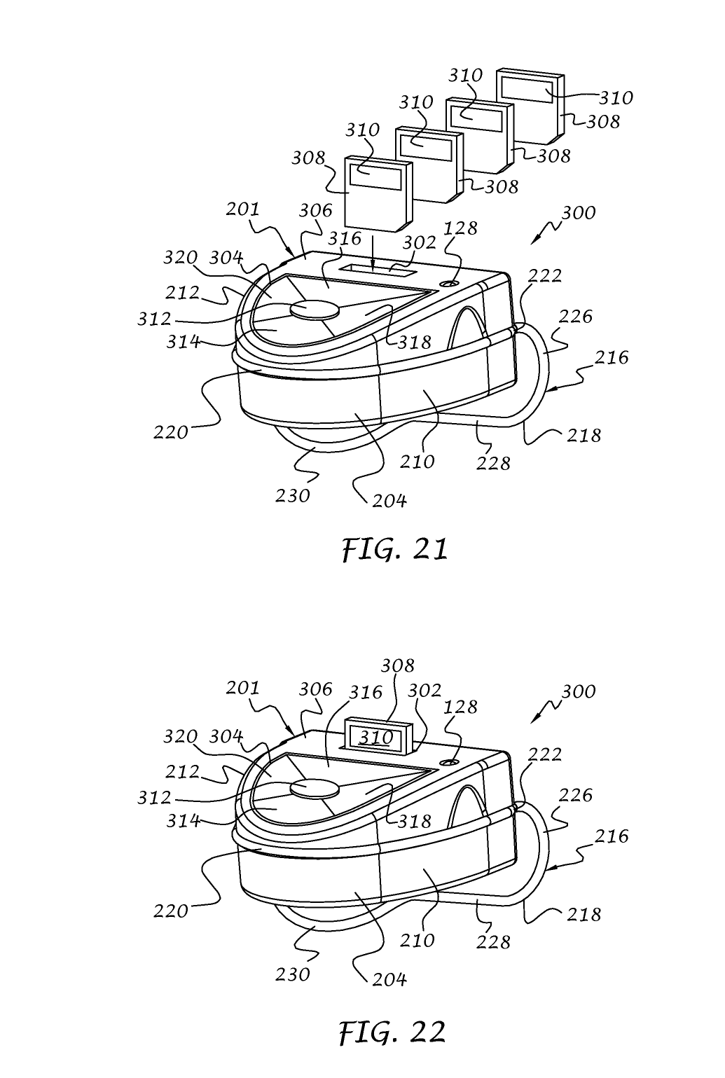

Referring now to FIGS. 21-22, a sound generating device 300 in accordance with a further embodiment of the invention is illustrated. The sound generating device 300 is similar in construction to the device 200 previously described, with the exception that a receptacle 302 and control panel 304 are preferably provided in the upper housing portion 306. As shown, the receptacle 302 is sized to receive one or more portable memory modules 308. Preferably, each memory module 308 comprises a micro memory card or the like that is very small in size with a large flash memory capacity for storing music data and other files. A suitable micro memory card is currently known as the “microSD Transflash” provided by SanDisk of Milpitas, Calif., and has approximate dimensions of 15 mm long×11 mm wide×1 mm thick and comes in different memory sizes of 512 megabytes (MB), 1 gigabyte (GB) and 2 GB. However, it will be understood that any suitable memory card capable of storing music data with a variety of different dimensions, storage capacities and memory types can be used. Although the receptacle 302 and control panel 304 are shown associated with an upper wall of the upper housing portion 306, it will be understood that the receptacle and/or control panel may be located on the side, front, rear, top and/or bottom walls of the housing.

As shown, a plurality of interchangeable memory modules 308 can be used to store, by way of example only, different musical genres, styles, artists, themes, and so on in Mp3 format or any other suitable format. In this manner, a virtual “library” of music can be easily carried by a user. When it is desired to hear a particular musical style, artist, theme and so on, the user need only remove one module 308 and replace it with another. To that end, a label or display 310 may be provided on each module 308 to identify the contents thereof. The display may be of the LCD type or other well-known types.

The control panel 304 preferably includes a central button or selector switch 312 and a plurality of buttons or selector switches 314, 316, 318 and 320 for operating the sound generating device 300. The buttons or switches may be of the membrane type or other well-known construction. By way of example only, the button 312 may be used to power the unit on and off, the buttons 318 and 320 may be used for fast forwarding, reversing, and/or selecting the next or previous song, while the buttons 314 and 316 may be used for accessing different musical styles, artists, etc. that may be present on the same module 308. It will be understood that the control panel 304 may have more or less buttons depending on the particular functions desired. A display may be associated with the upper housing portion 306 and/or the memory module 308 for displaying information related to the song being played or selected.

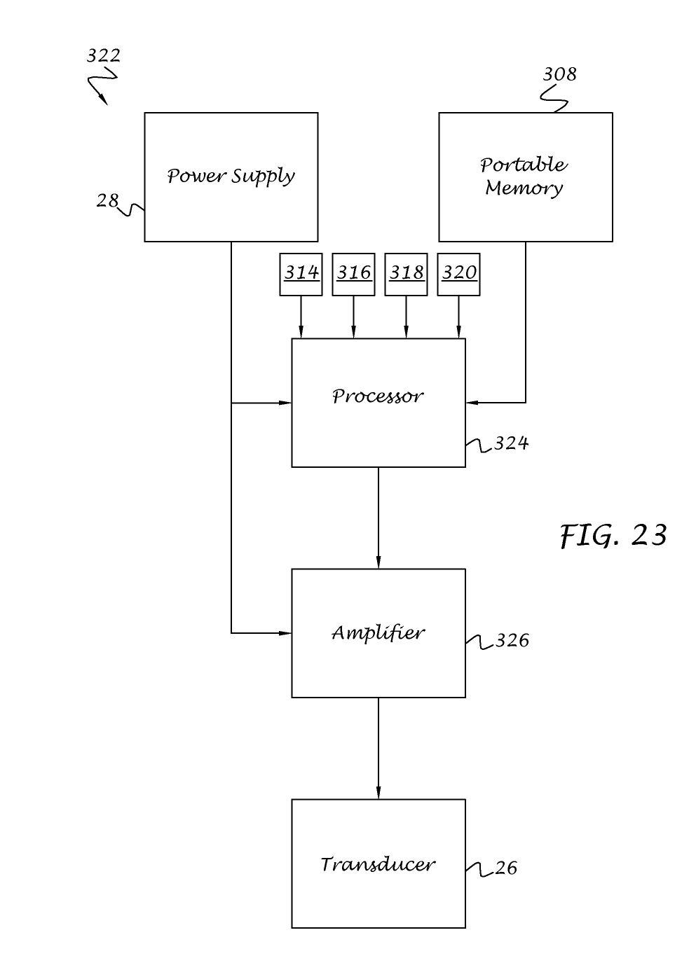

Referring now to FIG. 23, electrical circuitry 322, shown in the form of a block diagram, preferably includes a processor 324 connected to the selector switches 314-320 and the portable memory 308 for receiving and processing control signals from the switches and audio signals from the memory. An amplifier 326 receives audio signals from the processor 324 and sends them to the transducer 26 (FIG. 4) for generating sound, as previously described. A power supply 28 provides electrical power to the processor 324 and amplifier 326. The power supply 28, amplifier 326 and transducer 26 may be similar to those components previously described. The processor 324 is preferably in the form of a microprocessor but may alternatively comprise a microcomputer, programmable logic device, discrete logic and/or analog components, and so on.

Although an input jack (not shown) may be associated with the sound generating device 300 for receiving audio signals from an outside source such as an mP3 player or the like, such is not necessary since the device 300 is totally self-contained when the memory module 308 is installed for generating sound when the device is placed against a surface, as previously described.

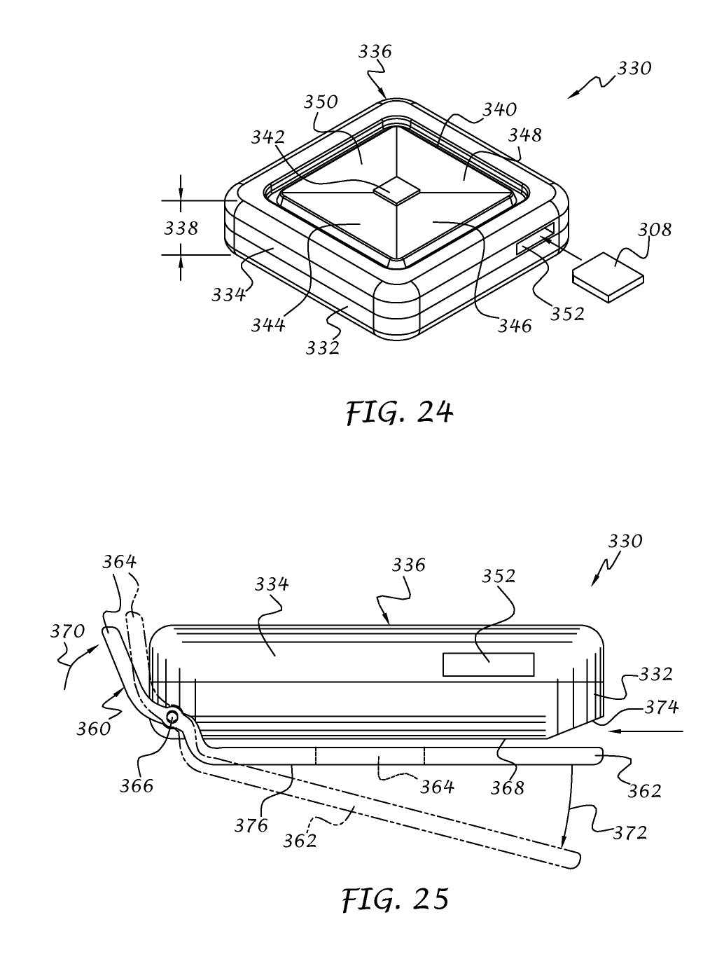

Referring now to FIG. 24, a sound generating device 330 in accordance with a further embodiment of the invention is illustrated. The sound generating device 330 is similar in construction to the device 300 previously described, with the exception that a the lower housing portion 332 and upper housing portion 334 together form a square-shaped housing 336 with a height 338 that is relatively small in comparison with the previous embodiment. It will be understood that the housing 336 is not limited to the square shape but may alternatively be formed as rectangular, circular, triangular, octagonal, or any other desired shape.

The upper housing portion 334 preferably includes a control panel 340 with a central button or selector switch 342 and a plurality of buttons or selector switches 344, 346, 348 and 350 for operating the sound generating device 330 as previously described. Although not shown, a display may be associated with the upper housing portion 306 and/or the memory module 308 for displaying information related to the song being played or selected. A receptacle 352 is preferably provided in the upper housing portion 334 for receiving one or more portable memory modules 308 as previously described. As in the previous embodiment, the receptacle 352 and/or control panel 340 may alternatively be located on the side, front, rear, top and/or bottom walls of the upper and lower housing portions.

Although a mounting device is not shown, it will be understood that any mounting device as previously described may be associated with the housing 336. In addition, and referring to FIG. 25, a mounting device 360 in accordance with a further embodiment of the invention is shown connected to the housing 336. The mounting device 360 preferably includes a clip portion 362 with an opening 364 (shown in hidden line) for accommodating the transducer 26 (FIG. 4) when the clip portion is placed on a surface and a lever arm portion 364 extending upwardly and rearwardly from the clip portion. The clip portion can be as wide and long as the housing 336 or may be wider and/or longer or narrower and/or shorter. A spring hinge 366 of well known construction is connected to the mounting device 360 and the lower housing portion 332 for biasing the clip portion 362 toward the lower surface 368 of the lower housing portion.

In use, the lever arm 364 is pressed toward the upper housing portion 334, as shown by arrow 370, to cause the clip portion 362 to rotate downwardly away from the lower surface 368, as shown by arrow 372, and create a space for inserting a panel (not shown) or the like. When the lever arm is released, the clip portion will rotate upwardly toward the panel to thereby hold the sound generating device 330 on the panel. In this manner, the vibrating transducer will be in contact with the panel to thereby transform the panel into a loudspeaker as previously described in reference to the previous embodiments. In order to facilitate insertion of the panel between the housing 336 and the clip portion 362, a chamfered surface 374 may be formed on the lower housing portion 332. When it is impractical to use the clip for mounting the sound generating device 330 to a surface, the clip may be removable and/or a lower surface 376 of the clip may include an adhesive layer, hook and loop material, and so on, for mounting to a surface.

It will be understood that the term “preferably” as used throughout the specification refers to one or more exemplary embodiments of the invention and therefore is not to be interpreted in any limiting sense. It will be further understood that terms of orientation and/or position as may be used throughout the specification denote relative, rather than absolute orientations and/or positions.

It will be appreciated by those skilled in the art that changes could be made to the embodiments described above without departing from the broad inventive concept thereof. It will be understood, therefore, that the present invention is not limited to the particular embodiments disclosed, but also covers modifications within the spirit and scope of the invention as defined by the appended claims.

What is claimed is:

1. A sound generating device for transforming an object into a loudspeaker, the sound generating device comprising:
a portable memory module adapted for storing audio signals;
a housing having a receptacle for receiving the portable memory module;
an exciter module located within the housing and operably associated with the portable memory module for generating vibrations at audio frequencies in response to audio signals associated with the portable memory module, the exciter module being connectable to an object to vibrate the object at the audio frequencies to thereby transform the object into a loudspeaker.

2. A sound generating device according to claim 1, wherein the exciter module emits no sound or low level sound when separated from the object and causes the object to emit substantially more sound when connected thereto.

3. A sound generating device according to claim 1, and further comprising a processor operably associated with the portable memory module and the exciter module.

4. A sound generating device according to claim 3, and further comprising an amplifier connected between the processor and the exciter module for amplifying audio signals associated with the processor and memory module.

5. A sound generating device according to claim 4, wherein the exciter module comprises a transducer electrically connected to the amplifier, the transducer being actuated in response to the audio signals to vibrate at audio frequencies.

6. A sound generating device according to claim 3, and further comprising at least one selector switch located on the housing and operably connected to the processor for operating the sound generating device.

7. A sound generating device according to claim 3, wherein the exciter module further comprises a movable wall section formed on the housing for movement with the transducer when actuated.

8. A sound generating device according to claim 7, wherein the movable wall section is spaced from the transducer when the exciter module is not connected to an object and the movable wall section moves into contact with the transducer when the exciter module is connected to the object.

9. A sound generating device according to claim 7, wherein the movable wall section is connected to the housing via flexible webs.

10. A sound generating device according to claim 7 wherein the movable wall section is separate from the housing.

11. A sound generating device according to claim 1, and further comprising a mounting device for connecting the sound generating device to an object.

12. A sound generating device according to claim 11, wherein the mounting device comprises a spring clip removably connected to the housing and extending in proximity to the exciter module such that an object positioned between the spring clip and housing causes the exciter module to contact the object.

13. A sound generating device according to claim 11, wherein the mounting device comprises a clip section and a lever arm section rotatably connected to the housing, the clip section being biased toward the housing and rotatable away from the housing when a force is applied to the lever arm.

14. A sound generating device according to claim 1, wherein the portable memory module comprises a display.

15. A loudspeaker comprising the sound generating device of claim 1, and further comprising a panel attached to the exciter module.

16. A loudspeaker according to claim 15, wherein the panel forms part of a wear article.

17. A sound generating device for transforming a panel into a loudspeaker, the sound generating device comprising:
a portable memory module adapted for storing audio signals;
a housing having an upper housing portion and a lower housing portion connected to the upper housing portion, the lower housing portion having a movable wall section for contacting a surface of the panel a receptacle formed in the housing for receiving the portable memory module;
an electro-mechanical assembly located within the housing and including:
a printed circuit board mounted in the upper housing portion;
a transducer suspended from the printed circuit board and extending into the lower housing portion;
the transducer including a stationary magnet and a movable plunger having an electrical coil in electrical communication with the printed circuit board;
the printed circuit board containing electrical circuitry for energizing the coil in response to a received audio signal from the portable memory module and moving the plunger with respect to the stationary magnet in proportion to the received audio signal;
the movable wall section being connected to a lower end of the plunger for movement therewith; and
a mounting device connected to the housing for removably connecting the housing to the panel such that the panel is vibrated in proportion to movement of the movable wall section to thereby transform the panel into a loudspeaker.

18. A sound generating device according to claim 17, wherein the electrical circuitry comprises:
a processor operably associated with the portable memory module; and
an amplifier connected between the processor and the transducer for amplifying audio signals associated with the processor and memory module.

19. A sound generating device according to claim 18, and further comprising at least one selector switch located on the housing and operably connected to the processor for operating the sound generating device.

20. A sound generating device according to claim 17, wherein the mounting device comprises a clip section and a lever arm section rotatably connected to the housing, the clip section being biased toward the housing and rotatable away from the housing when a force is applied to the lever arm.
